(19) United States
(12) Patent Application Publication
(10) Pub. No.: US 2010/0032719 A1
(43) Pub. Date: Feb. 11, 2010

(54) PROBES FOR SCANNING PROBE MICROSCOPY

(76) Inventors: Seunghun HONG, Seoul (KR); Taekyeong KIM, Pyeongtaek-si (KR)

Correspondence Address: Seunghun Hong;Song-Pa-Gu, Jam-Sil-Dong, Asia-Seon-Su-Chon, Apt 6-205, Seoul, KR

(21) Appl. No.: 12/248,652

(22) Filed: Oct. 9, 2008

(30) Foreign Application Priority Data
Aug. 8, 2008 (KR) 10-2008-0078047

(51) Int. Cl. H01L 21/20; H01L 29/205

(52) U.S. Cl. 257/201; 438/483; 257/E29.091; 257/E21.09

(57) ABSTRACT

Disclosed are probes for scanning probe microscopy comprising a semiconductor heterostructure and methods of making the probes. The semiconductor heterostructure determines the optical properties of the probe and allows for optical imaging with nanometer resolution.

### CROSS-REFERENCE TO RELATED APPLICATIONS

The present application claims priority to Korean Patent Application No. 10-2008-0078047 entitled “SPM Probes” filed on Aug. 8, 2008, and incorporated herein by reference in its entirety.

### BACKGROUND

Scanning probe microscopy (SPM) refers to a number of nano-scale imaging techniques that allow the properties of a variety of surfaces to be measured down to the atomic level by means of physical probes scanning the surfaces. SPM has come into the spotlight as the third-generation successor to optical microscopy and electron microscopy and is used in a variety of fields where measurements on a very small scale are required. Unlike optical microscopes and electron microscopes, scanning probe microscopes can operate not only in a vacuum or at atmospheric pressure, but also in a liquid. This property extends the range of applications of scanning probe microscopes to include, for example, bio-molecular detection such as the detection of cell division or structures within living cells.

### SUMMARY

In one aspect, a probe for scanning probe microscopy comprises a semiconductor heterostructure disposed on the tip of the probe. The heterostructure comprises a first layer of a first semiconductor adjacent to a layer of a second semiconductor and the bandgap of the first semiconductor is greater than the bandgap of the second semiconductor. The heterostructure may comprise AlGaAs/GaAs, InGaAs/GaAs, AlGaN/GaN, InGaN/GaN, or ZnS/MgZnS. However, the heterostructures may comprise other types of semiconductor layers and more than two layers of semiconductor. In other embodiments, the heterostructure comprises alternating layers of AlGaAs and GaAs, alternating layers of InGaAs and GaAs, alternating layers of AlGaN and GaN, alternating layers of InGaN and GaN, alternating layers of ZnS and MgZnS, or alternating layers of ZnS and CdS.

In other embodiments, the heterostructure further comprises a second layer of the first semiconductor and the layer of the second semiconductor is disposed between the first and second layers of the first semiconductor. The heterostructure may comprise AlGaAs/GaAs/AlGaAs, InGaAs/GaAs/InGaAs, AlGaN/GaN/AlGaN, InGaN/GaN/InGaN, or ZnS/CdS/ZnS. However, the heterostructures may comprise other types of semiconductor layers and more than three layers of semiconductor.

The diameter and height of the semiconductor heterostructure may vary. In some embodiments, the diameter of the heterostructure ranges from 10 nm to 1 μm, although other diameters are possible. In some embodiments, the height of the heterostructure ranges from 1 nm to 1 μm, although other heights are possible.

In another aspect, a method of forming a semiconductor heterostructure on a probe for scanning probe microscopy comprises depositing a first layer of a first semiconductor on the tip of the probe and depositing a layer of a second semiconductor on the first layer of the first semiconductor to provide the heterostructure. In some embodiments, the bandgap of the first and second semiconductors are different. In some such embodiments, the bandgap of the first semiconductor is greater than the bandgap of the second semiconductor. The heterostructure may comprise AlGaAs/GaAs, InGaAs/GaAs, AlGaN/GaN, InGaN/GaN, or ZnS/MgZnS, but other types of semiconductors are possible and more than two layers of semiconductor may be present.

In some embodiments, the method further comprises depositing a second layer of the first semiconductor on the layer of the second semiconductor. In some such embodiments, the bandgap of the first semiconductor is greater than the bandgap of the second semiconductor. In some embodiments, the heterostructure comprises AlGaAs/GaAs/AlGaAs, InGaAs/GaAs/InGaAs, AlGaN/GaN/AlGaN, InGaN/GaN/InGaN, or ZnS/CdS/ZnS, but other types of semiconductors are possible and more than three layers of semiconductor may be present.

In some embodiments, the method further comprises forming a mask layer on the tip of the probe and removing the distal end of the tip of the probe prior to depositing the first layer of the first semiconductor. In other embodiments, the method further comprises removing the mask layer after the semiconductor heterostructure is formed. The mask layer may comprise aluminum, titanium, silica, tin oxide, cobalt, palladium, silver, chromium, or lead, but other materials are possible. In some embodiments, the mask layer has a thickness ranging from 10 nm to 100 nm, but other thicknesses are possible.

In another aspect, scanning probe microscopes are provided. In some embodiments, the scanning probe microscope comprises a probe having a semiconductor heterostructure disposed on the tip of the probe. The heterostructure comprises a first layer of a first semiconductor adjacent to a layer of a second semiconductor and the bandgap of the first semiconductor is greater than the bandgap of the second semiconductor. In other embodiments, the probe further comprises a second layer of the first semiconductor and the layer of the second semiconductor is disposed between the first and second layers of the first semiconductor. In yet further embodiments, the microscope is adapted for fluorescence resonance energy transfer-near field scanning optical microscopy.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIGS. 1 and 2 show illustrative embodiments of SPM probes to which a semiconductor heterostructure can be applied.

FIG. 3 shows an illustrative embodiment of an SPM probe comprising a semiconductor heterostructure.

FIG. 4 shows an illustrative embodiment of a manufacturing process for an SPM probe comprising a semiconductor heterostructure.

### DETAILED DESCRIPTION

In the following detailed description, reference is made to the accompanying drawings, which form a part hereof. In the drawings, similar symbols typically identify similar components, unless context dictates otherwise. The illustrative embodiments described in the detailed description, drawings, and claims are not meant to be limiting. Other embodiments may be utilized, and other changes may be made, without departing from the spirit or scope of the subject matter presented here.

The present technology relates to probes for scanning probe microscopy (SPM probes) comprising a semiconductor heterostructure disposed on the tip of the probe. The term SPM probe as used herein refers to a probe used for SPM imaging, in which the degree of various interactions (e.g., tunneling current, atomic force, energy transfer or the like) occurring between the probe and a target sample is detected to form an image. SPM includes all microscopy techniques that can measure the surface properties of materials down to the atomic level. Non-limiting examples of SPM include: Scanning Tunneling Microscopy (STM), Atomic Force Microscopy (AFM), Magnetic Force Microscopy (MFM), Lateral Force Microscopy (LFM), Force Modulation Microscopy (FMM), Electrostatic Force Microscopy (EFM), Scanning Capacitance Microscopy (SCM), Electrochemistry SPM (EC-SPM), Scanning Thermal Microscopy (SThM), Near-Field Scanning Optical Microscopy (NSOM), and so forth.

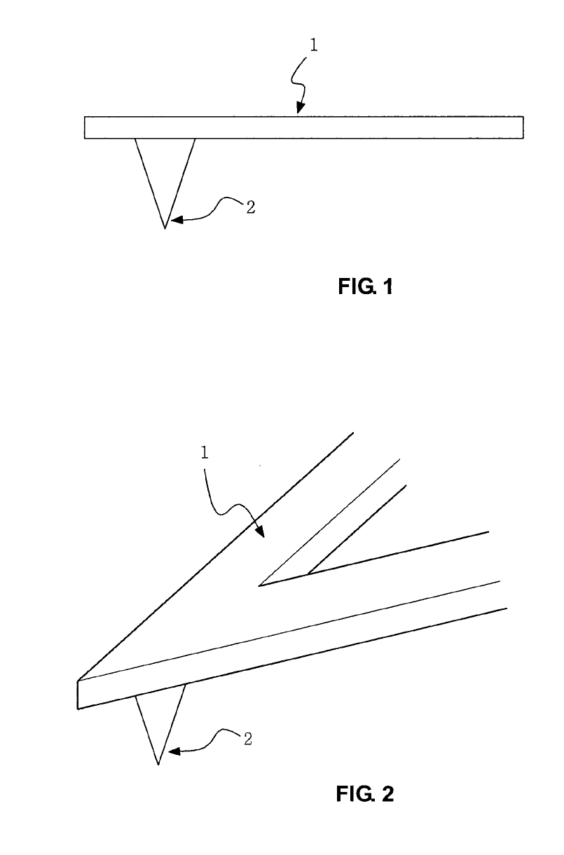

FIG. 1 shows a basic SPM probe that includes a flexible cantilever beam 1 and a sharp tip 2 formed at a distal end of the cantilever beam 1. The V-shaped cantilever beam 1 shown in FIG. 2 provides less physical resistance with respect to a change in the vertical direction. Probes of various other shapes may also used. SPM probes are typically manufactured by various etching methods (e.g., chemical etching or plasma etching) or a lithography method using silicon (Si) or silicon nitride (Si₃N₄). The SPM probes described above are merely examples of SPM probes to which a semiconductor heterostructure can be applied.

The disclosed SPM probes comprise a semiconductor heterostructure disposed on the tip of the probe. In some embodiments, the heterostructure includes a first layer of a first semiconductor adjacent to a layer of a second semiconductor. The bandgaps of the first and second semiconductors may be different. In some embodiments, the bandgap of the first semiconductor is greater than the bandgap of the second semiconductor. The semiconductor materials may vary and may be selected by considering the imaging technique to which the probe is applied and the optical properties of the sample to be detected. In some embodiments, the heterostructure is AlGaAs/GaAs. By “AlGaAs/GaAs,” it is meant a layer of AlGaAs adjacent to a layer of GaAs. In other embodiments, the heterostructure is InGaAs/GaAs, AlGaN/GaN, InGaN/GaN, or ZnS/MgZnS.

The semiconductor heterostructure may comprise other layers of semiconductor. In some embodiments, the heterostructure comprises alternating layers of AlGaAs and GaAs, alternating layers of InGaAs and GaAs, alternating layers of AlGaN and GaN, alternating layers of InGaN and GaN, alternating layers of ZnS and CdS, alternating layers of ZnSe and ZnMgSSe, or alternating layers of ZnS and MgZnS.

In other embodiments, the heterostructure further includes a second layer of the first semiconductor adjacent to the layer of the second semiconductor such that the layer of the second semiconductor is disposed between the first and second layers of the first semiconductor. In some such embodiments, the heterostructure is AlGaAs/GaAs/AlGaAs, InGaAs/GaAs/InGaAs, AlGaN/GaN/AlGaN, InGaN/GaN/InGaN, ZnS/CdS/ZnS, or ZnSe/ZnMgSSe/ZnMgSSe.

At least some of the semiconductor heterostructures described above provide a quantum well structure. By way of example only, the AlGaAs/GaAs/AlGaAs heterostructure (a layer of GaAs sandwiched between layers of AlGaAs) provides such a quantum well structure. The bandgap of AlGaAs is greater than the bandgap of GaAs, thereby forming a potential well in the multilayer structure.

The disclosed SPM probes have the ability to absorb and/or emit light. The optical properties of the probes, including the absorption and emission characteristics, are determined by the semiconductor heterostructure formed on the tip of the probe. The wavelength of light absorbed or emitted by the semiconductor heterostructure can be tuned by controlling the type of semiconductor and the thickness of the semiconductor layers in the heterostructure. In some embodiments, it may be desirable to tune the optical properties of the probe based on the optical properties (e.g., fluorescence) of the sample and the type of the detector.

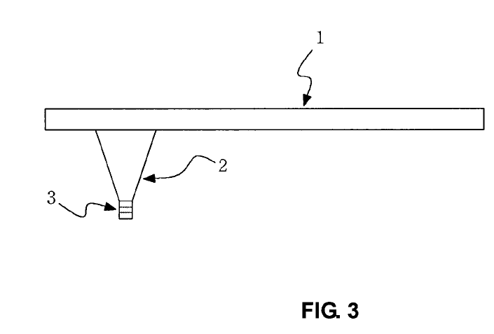

In order to form a high resolution image with the disclosed SPM probes, the semiconductor heterostructure may be included only at the distal end of the probe tip, as opposed to a semiconductor heterostructure disposed over the entire probe tip. FIG. 3 illustrates a SPM probe having a semiconductor heterostructure disposed on the distal end of the tip of the probe.

The dimensions of the semiconductor heterostructure may vary. The horizontal dimension (diameter) of the semiconductor may be in the range of approximately 10 nm to 1 μm, approximately 10 nm to 500 nm, approximately 10 nm to 100 nm, approximately 10 nm to 50 nm, approximately 50 nm to 1 μm, approximately 50 nm to 500 nm, approximately 50 nm to 100 nm, approximately 100 nm to 1 μm, approximately 100 nm to 500 nm, or approximately 500 nm to 1 μm. This includes embodiments in which the diameter is approximately 10 nm, 50 nm, 100 nm, 200 nm, 500 nm, 750 nm, or 1,000 nm. By “horizontal dimension” it is meant a dimension of the semiconductor heterostructure defined along an axis parallel to the cantilever beam.

Similarly, the vertical dimension (height) of the semiconductor heterostructure may vary. By “vertical dimension” it is meant a dimension of the semiconductor heterostructure defined along an axis orthogonal to the cantilever beam. In some embodiments, the height is in the range of 1 nm to 1 μm, approximately 1 nm to 500 nm, approximately 1 nm to 100 nm, approximately 1 nm to 50 nm, approximately 1 nm to 10 nm, approximately 10 nm to 500 nm, approximately 10 nm to 100 nm, approximately 10 nm to 50 nm, approximately 50 nm to 1 μm, approximately 50 nm to 500 nm, approximately 50 nm to 100 nm, approximately 100 nm to 1 μm, approximately 100 nm to 500 nm, or approximately 500 nm to 1 μm. This includes embodiments in which the height is approximately 1 nm, 10 nm, 50 nm, 100 nm, 500 nm or 1,000 nm.

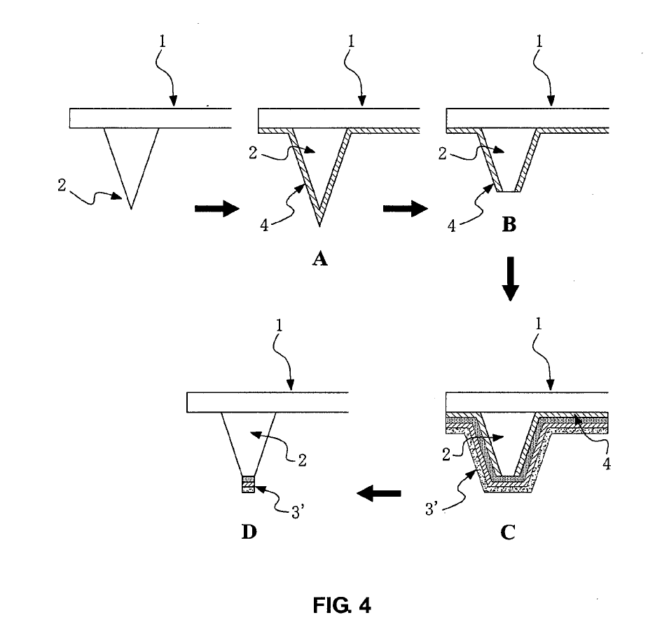

The SPM probes disclosed herein may be manufactured by various methods. One illustrative embodiment of such a method is shown in FIG. 4. The method comprises forming a mask layer 4 on the tip 2 of the probe (FIG. 4A); removing the distal end of the tip of the probe (FIG. 4B); forming a semiconductor heterostructure 3′ on the tip of the probe (FIG. 4C); and removing the mask layer 4 from the probe (FIG. 4D).

A variety of materials may be used to form the mask layer including, but not limited to, aluminum (Al), titanium (Ti), silica (SiO₂), tin oxide, cobalt (Co), palladium (Pd), silver (Ag), chromium (Cr) or lead (Pb). However, the material of the mask layer is not particularly limited, provided the material can be uniformly formed on the SPM probe by various deposition methods and can be easily removed if necessary. The thickness of the mask layer may also vary. In some embodiments, the thickness ranges from 10 nm to 100 nm.

The mask layer may be formed by a variety of methods, including, but not limited physical vapor deposition (PVD) or chemical vapor deposition (CVD). Exemplary PVD methods include, but are not limited to thermal evaporation, DC sputtering, RF sputtering, ion beam sputtering, pulsed laser deposition or molecular beam epitaxy. Exemplary CVD methods include, but are not limited to thermal CVD, low pressure CVD, plasma enhanced CVD or metal-organic CVD. However, these methods are merely examples, and any method could be employed as long as it can form the mask layer uniformly on the SPM probe.

As shown in FIG. 4B, the distal end of the tip of the probe may be removed after the mask layer is formed. The method of removing the distal end of the tip is not particularly limited. For example, the distal end of the tip may be removed by polishing the end of the tip with a solid substrate (e.g., silica (SiO₂)). This polishing step may be accomplished in a variety of ways. For example, the SPM probe having the mask layer may be mounted on a piece of equipment such as a scanning probe microscope. The microscope may be driven to scan the solid substrate at a constant pressure, while keeping the tip in contact with the solid substrate. However, other means of carrying out the polishing step may be employed.

In another embodiment, the distal end of the tip may be removed by a chemical mechanical polishing (CMP) process. CMP is commonly used to planarize a wafer surface in a semiconductor manufacturing process. However, it may be effectively applied to the tip removal process disclosed herein.

The conditions of the tip polishing process or the CMP process may be adjusted to provide the desired diameter of the cut tip. In some embodiments, the diameter of the cross-section of the distal end of the tip may be in the range of approximately 10 nm to 1 μm, approximately 10 nm to 1 μm, approximately 10 nm to 500 nm, approximately 10 nm to 100 nm, approximately 10 nm to 50 nm, approximately 50 nm to 1 μm, approximately 50 nm to 500 nm, approximately 50 nm to 100 nm, approximately 100 nm to 1 μm, approximately 100 nm to 500 nm or approximately 500 nm to 1 μm.

As shown in FIG. 4C, a semiconductor heterostructure may be formed on the tip of the SPM probe after the distal end of the tip has been removed. The semiconductor heterostructure may be formed by depositing a first layer of a first semiconductor on the tip of the probe and depositing a layer of a second semiconductor on the first layer of the first semiconductor. As discussed above, the bandgap of the first and second semiconductors may be different. In some embodiments, the bandgap of the first semiconductor is greater than the bandgap of the second semiconductor. Other layers of semiconductor may be deposited to form other heterostructures. In some embodiments, a second layer of the first semiconductor may be deposited on the layer of the second semiconductor. The types of semiconductor layers and resulting heterostructures may vary as discussed above.

The step of forming the semiconductor heterostructure may be accomplished in a variety of ways. By way of example only, deposition of the semiconductor layers may be accomplished by any of the PVD or CVD methods described above.

In one embodiment, the semiconductor heterostructure is formed by molecular beam epitaxy. In molecular beam epitaxy, molecular beams formed by the evaporation of the relevant atoms are irradiated on the substrate (SPM probe). Molecular beam epitaxy is carried out under a high vacuum, which minimizes contamination of the substrate. Molecular beam epitaxy also allows the growing semiconductor heterostructure to be separated from the source of materials for forming the semiconductor heterostructure. The amount of source material supplied to the growing semiconductor heterostructure can be accurately controlled by a shutter. Accordingly, the growing semiconductor heterostructure and the supply of materials can be independently monitored and adjusted for precise control over the thickness, growth direction, and composition of the deposited semiconductor heterostructure.

Conditions for forming the semiconductor heterostructures using any of the methods disclosed above are not particularly limited and may be adjusted according to the desired semiconductor heterostructure to be formed. By way of example only, when the semiconductor heterostructure is formed by molecular beam epitaxy, the temperature of the evaporation source may be approximately 500° C. to 1,200° C. (e.g., approximately 500° C., 600° C., 700° C., 800° C., 900° C., 1,000° C., 1,100° C., 1,200° C. or appropriate combinations/ranges thereof); the crystal growth temperature in the chamber may be 500° C. to 700° C. (e.g., approximately 500° C., 550° C., 600° C., 650° C., 700° C. or appropriate combinations/ranges thereof); and the irradiation rate of the molecular beam may be approximately 0.1 μm/h to 1 μm/h (e.g., 0.1 μm/h, 0.25 μm/h, 0.5 μm/h, 0.75 μm/h, 1 μm/h or appropriate combinations/ranges thereof). However, other conditions are possible.

As shown in FIG. 4D, the mask layer may be removed after the semiconductor heterostructure is formed. Any portion of the semiconductor heterostructure disposed over the mask layer may also be removed during this process, so that only the semiconductor heterostructure on the distal end of the tip remains. A variety of methods may be used to remove the mask layer. For example, the SPM probe may be treated with an appropriate etchant corresponding to the material used for the mask layer. By way of example, when the mask layer is formed of aluminum, a mixture of phosphoric acid, nitric acid, and acetic acid may be used as the etchant. However, other etchants may be used.

Also disclosed are scanning probe microscopes including any of the SPM probes described herein. In some embodiments, the scanning probe microscope is adapted for Fluorescence Resonance Energy Transfer-Near Field Scanning Optical microscopy (“FRET-NSOM”).

The mechanism of the NSOM technique is based on detecting near-field effects that are locally induced by a sharp probe. The optical resolution of NSOM can be enhanced by exploiting the FRET phenomenon. FRET involves nonradiative energy transfer from an excited donor (e.g., the SPM probe or the sample) and an unexcited acceptor (e.g., the sample or the SPM probe). The nonradiative energy transfer is strongly distance dependent. By way of example only, a SPM probe including the appropriate semiconductor heterostructure can absorb light of a specific wavelength from an excitation source (e.g., a laser). When the semiconductor heterostructure comes within sufficient distance of the sample (e.g., fluorescently labeled biomolecules), nonradiative energy transfer occurs between the probe and the sample. The nonradiative energy transfer causes the fluorescence of the sample and/or SPM probe to shift. These fluorescence shifts can be detected and imaged.

The SPM probes disclosed herein are able to achieve optical imaging of a variety of samples with nanometer resolution and are readily adaptable for use with a variety of detectors. The semiconductor heterostructures have narrow emission spectra, which can be tuned by adjusting the type and thickness of the semiconductor layers in the heterostructure, as discussed above. Thus, the optical properties of the semiconductor heterostructures may span a range of wavelengths from infrared to ultraviolet, providing great flexibility over the kinds of samples studied and detectors employed.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

### EQUIVALENTS

The present disclosure is not to be limited in terms of the particular embodiments described in this application. Many modifications and variations can be made without departing from its spirit and scope, as will be apparent to those skilled in the art. Functionally equivalent methods and apparatuses within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can, of course, vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth. Unless otherwise specified, “a” or “an” means “one or more.”

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A probe for scanning probe microscopy, comprising a semiconductor heterostructure disposed on the tip of the probe, wherein the heterostructure comprises a first layer of a first semiconductor adjacent to a layer of a second semiconductor, wherein the bandgap of the first semiconductor is greater than the bandgap of the second semiconductor.

2. The probe of claim 1, wherein the heterostructure comprises AlGaAs/GaAs, InGaAs/GaAs, AlGaN/GaN, InGaN/GaN, or ZnS/MgZnS.

3. The probe of claim 1, wherein the heterostructure comprises alternating layers of AlGaAs and GaAs, alternating layers of InGaAs and GaAs, alternating layers of AlGaN and GaN, alternating layers of InGaN and GaN, alternating layers of ZnS and MgZnS, or alternating layers of ZnS and CdS.

4. The probe of claim 1, wherein the heterostructure further comprises a second layer of the first semiconductor and the layer of the second semiconductor is disposed between the first and second layers of the first semiconductor.

5. The probe of claim 4, wherein the heterostructure comprises AlGaAs/GaAs/AlGaAs, InGaAs/GaAs/InGaAs, AlGaN/GaN/AlGaN, InGaN/GaN/InGaN, or ZnS/CdS/ZnS.

6. The probe of claim 1, wherein the diameter of the heterostructure ranges from 10 nm to 1 μm.

7. The probe of claim 1, wherein the height of the heterostructure ranges from 1 nm to 1 μm.

8. A method of forming a semiconductor heterostructure on a probe for scanning probe microscopy, the method comprising:
depositing a first layer of a first semiconductor on the tip of the probe; and
depositing a layer of a second semiconductor on the first layer of the first semiconductor to provide the heterostructure, wherein the bandgap of the first and second semiconductors are different.

9. The method of claim 8, wherein the bandgap of the first semiconductor is greater than the bandgap of the second semiconductor.

10. The method of claim 8, wherein the heterostructure comprises AlGaAs/GaAs, InGaAs/GaAs, AlGaN/GaN, InGaN/GaN, or ZnS/MgZnS.

11. The method of claim 8, further comprising depositing a second layer of the first semiconductor on the layer of the second semiconductor.

12. The method of claim 11, wherein the bandgap of the first semiconductor is greater than the bandgap of the second semiconductor.

13. The method of claim 11, wherein the heterostructure comprises AlGaAs/GaAs/AlGaAs, InGaAs/GaAs/InGaAs, AlGaN/GaN/AlGaN, InGaN/GaN/InGaN, or ZnS/CdS/ZnS.

14. The method of claim 8, further comprising forming a mask layer on the tip of the probe and removing the distal end of the tip of the probe prior to depositing the first layer of the first semiconductor.

15. The method of claim 14, further comprising removing the mask layer after the semiconductor heterostructure is formed.

16. The method of claim 14, wherein the mask layer comprises aluminum, titanium, silica, tin oxide, cobalt, palladium, silver, chromium, or lead.

17. The method of claim 14, wherein the mask layer has a thickness ranging from 10 nm to 100 nm.

18. A scanning probe microscope comprising the probe of claim 1.

19. A scanning probe microscope comprising the probe of claim 4.

20. The scanning probe microscope of claim 19, wherein the microscope is adapted for fluorescence resonance energy transfer-near field scanning optical microscopy.
